(19) United States
(12) Patent Application Publication
(10) Pub. No.: US 2009/0085185 A1
(43) Pub. Date: Apr. 2, 2009

(54) STACK-TYPE SEMICONDUCTOR PACKAGE, METHOD OF FORMING THE SAME AND ELECTRONIC SYSTEM INCLUDING THE SAME

(75) Inventors: Hak-Kyoon BYUN, Chungcheongnam-do (KR); Tae-Hun KIM, Chungcheongnam-do (KR); Sang-Uk HAN, Gyeonggi-do (KR); Jung-Do LEE, Gyeonggi-do (KR); Seon-Hyang YOU, Daejeon (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/238,781

(22) Filed: Sep. 26, 2008

(30) Foreign Application Priority Data
Oct. 1, 2007 (KR) 2007-0098705

(51) Int. Cl. H01L 23/538

(52) U.S. Cl. 257/686; 257/E23.169

(57) ABSTRACT

A stack-type semiconductor package, a method of forming the same, and an electronic system including the same are provided. The stack-type semiconductor package includes: a lower printed circuit board having a plurality of connection bumps disposed on an upper surface of the lower printed circuit board and a plurality of lower interconnections; at least one first lower chip sequentially stacked on the lower printed circuit board and electrically connected to the plurality of lower interconnections; a lower molding resin compound disposed on the lower printed circuit board and covering the first lower chips; a double-sided wiring board bonded to the lower molding resin compound and electrically connected to the connection bumps; and an upper chip package bonded to the double-sided wiring board and having upper bumps electrically connected to an interconnection pattern of the double-sided wiring board.

### CROSS-REFERENCE TO RELATED APPLICATIONS

This application claims priority under 35 U.S.C §119 to Korean Patent Application No. 10-2007-0098705, filed on Oct. 1, 2007, the contents of which are hereby incorporated herein by reference in their entirety.

### BACKGROUND

The present inventive concept relates to a semiconductor package, a method of forming the same, and an electronic system including the same. More particularly, the present inventive concept relates to a stack-type semiconductor package, a method of forming the same, and an electronic system including the same.

Demand for decreased size and increased functionality of electronic products has driven research into ways of increasing the integration density of semiconductor devices in the electronic products. Increases in integration density have been researched both at the wafer level and at the semiconductor package level. In the semiconductor package level, two or more semiconductor chips or semiconductor packages can be integrated into one stack-type semiconductor package. However, stack-type semiconductor packages often experience problems accommodating high pin-count semiconductor devices. Further, stack-type semiconductor packages often experience failures due to warpage caused by excessive heat generation in localized areas of the packages.

### SUMMARY

An example embodiment of the inventive concept provides a stack-type semiconductor package capable of electrically connecting a lower chip package to an upper chip package. The stack-type semiconductor package allows for chip packages having a high pin-count for improving the integration density in the package. The stack-type semiconductor package also increases a molding region of a lower package to prevent warpage of the lower package, and improves the mechanical reliability of the package. A method of forming the stack-type semiconductor package and an electronic system including the same are also provided.

### BRIEF DESCRIPTION OF THE DRAWINGS

The foregoing and other objects, features and advantages of the inventive concept will be apparent from the detailed description of example embodiments, in conjunction with the accompanying drawings. The drawings are not necessarily to scale, emphasis instead being placed upon illustrating the principles of the inventive concept.

FIG. 1 is a plan view of a double-sided wiring board according to example embodiments of the present inventive concept.

FIG. 2A is a cross-sectional view taken along the line I-I′ of FIG. 1, illustrating a double-sided wiring board according to example embodiments of the present inventive concept.

FIG. 2B is a cross-sectional view taken along line I-I′ of FIG. 1, illustrating a double-sided wiring board according to other example embodiments of the present inventive concept.

FIGS. 3A to 3D are cross-sectional views illustrating a method of forming a stack-type semiconductor package according to example embodiments of the present inventive concept.

FIGS. 4A and 4B are cross-sectional views illustrating a method of forming a stack-type semiconductor package according to other example embodiments of the present inventive concept.

FIG. 5 is a cross-sectional view illustrating a method of forming a stack-type semiconductor package according to still other example embodiments of the present inventive concept.

FIG. 6 is a cross-sectional view illustrating a method of forming a stack-type semiconductor package according to yet other example embodiments of the present inventive concept.

FIG. 7 is a schematic block diagram of an electronic system including a stack-type semiconductor package according to example embodiments of the present inventive concept.

FIG. 8 is a schematic diagram of a memory module, in which a stack-type semiconductor package is mounted, according to example embodiments of the present inventive concept.

### DETAILED DESCRIPTION OF THE EMBODIMENTS

The present inventive concept will now be described more fully hereinafter with reference to the accompanying drawings, in which example embodiments of the inventive concept are shown. The inventive concept may, however, be embodied in different forms and should not be construed as limited to the example embodiments set forth herein. Rather, these example embodiments are provided so that this disclosure will be thorough and complete, and will fully convey the scope of the inventive concept to those skilled in the art. In the drawings, the thickness of layers and regions may be exaggerated for clarity. Also, when a layer is referred to as being “on” another layer or a substrate, it may be directly formed on the other layer or substrate or a third layer may be interposed therebetween. Like reference numerals designate like elements throughout the specification.

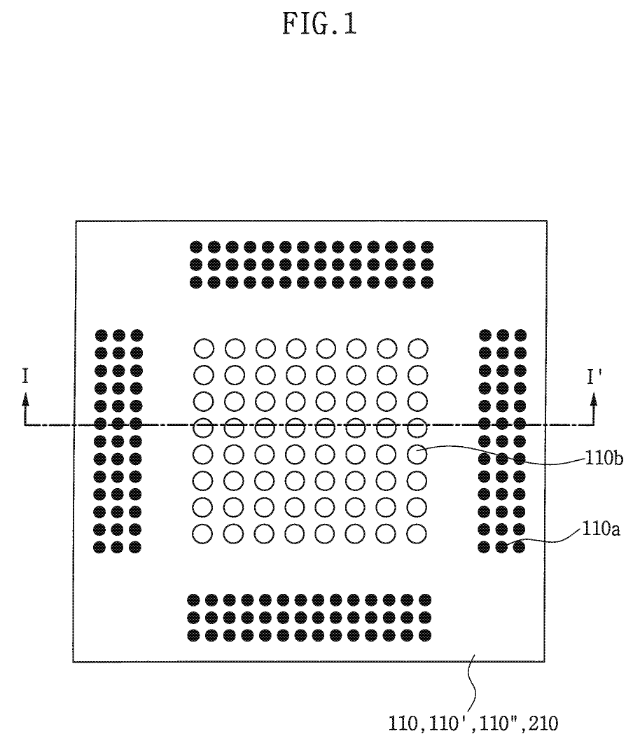

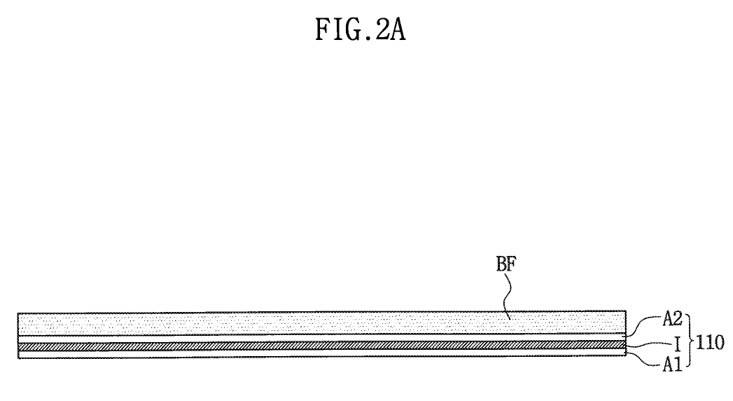

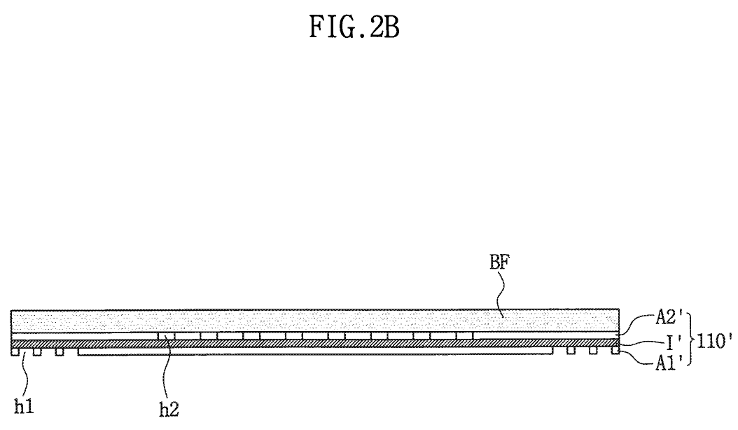

FIG. 1 is a plan view of a double-sided wiring board according to example embodiments of the present inventive concept, and FIG. 2A is a cross-sectional view taken along line I-I′ of FIG. 1, illustrating a double-sided wiring board according to example embodiments of the present inventive concept. Also, FIG. 2B is a cross-sectional view taken along line I-I′ of FIG. 1, illustrating a double-sided wiring board according to other example embodiments of the present inventive concept.

Referring to FIGS. 1 and 2A, the double-sided wiring board 110 may include a lower thermosetting resin layer A1 (also referred to as a first insulating layer), an interconnection pattern I, and an upper thermosetting resin layer A2 (also referred to as a second insulating layer), which are sequentially stacked. The double-sided wiring board 110 may have mechanical flexibility, i.e., may be formed of a flexible material. A backing film BF may be attached on the upper thermosetting resin layer A2. The interconnection pattern I may be formed as a copper (Cu) interconnection structure. The interconnection pattern I may include lower connection lands 110a and upper connection lands 110b. Lower surfaces of the lower connection lands 110a and upper surfaces of the upper connection lands 110b may be coated with a material such as Au, Ni, Pd, or Sn.

Alternatively, referring to FIGS. 1 and 2B, the double-sided wiring board 110′ may include a lower thermosetting resin layer A1′, an interconnection pattern I′, and an upper thermosetting resin layer A2′, which are sequentially stacked. The double-sided wiring board 110′ may have mechanical flexibility, i.e., may be formed of a flexible material. The interconnection pattern I′ may be formed as a Cu interconnection structure. The interconnection pattern I′ may include lower connection lands 110a and upper connection lands 110b. Lower surfaces of the lower connection lands 110a and upper surfaces of the upper connection lands 110b may be coated with a material such as Au, Ni, Pd, or Sn. The lower thermosetting resin layer A1′ may expose the lower connection lands 110a through lower via holes h1. Also, the upper thermosetting resin layer A2′ may expose the upper connection lands 110b through upper via holes h2. A backing film BF may be attached on the upper thermosetting resin layer A2′.

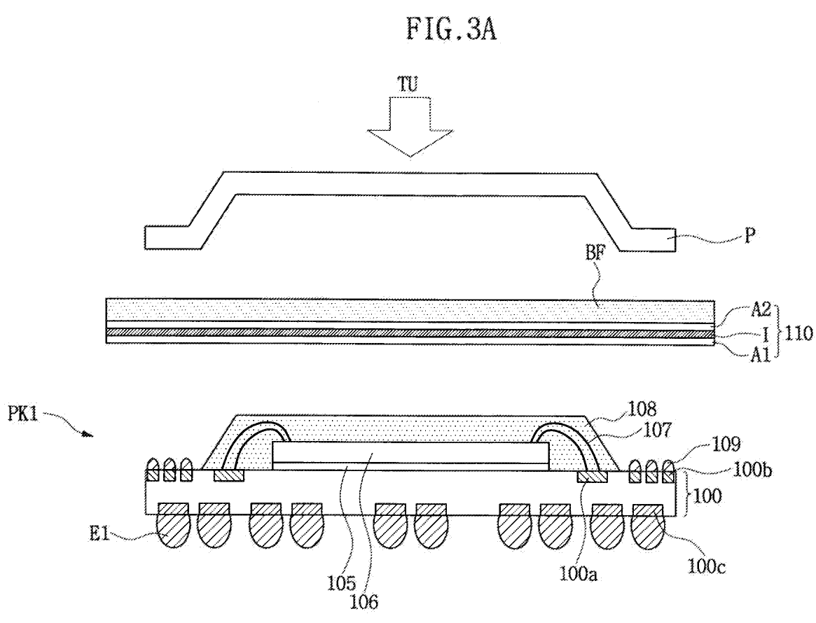

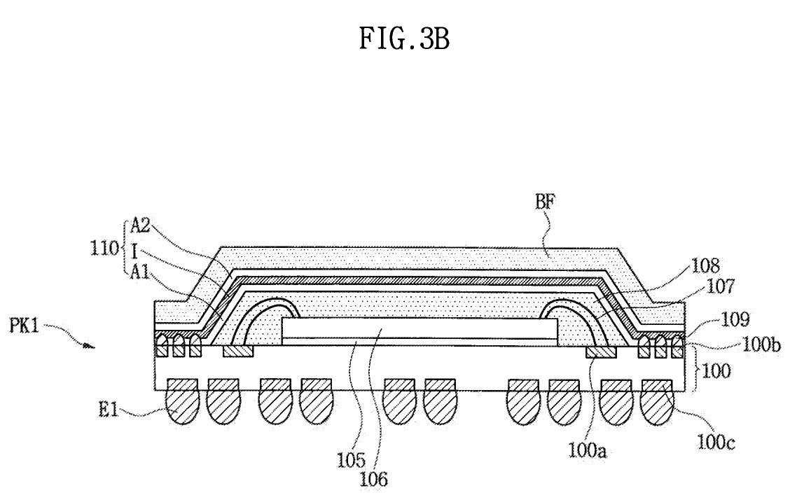

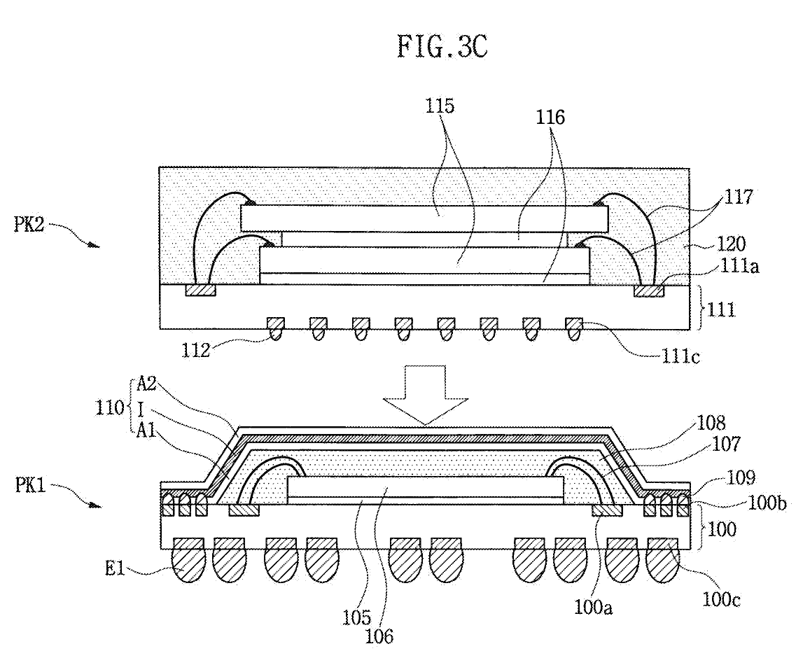

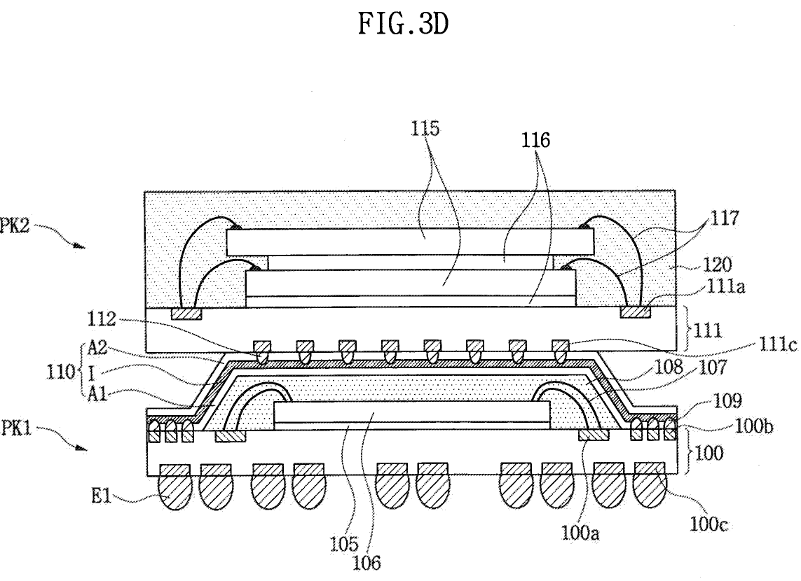

FIGS. 3A to 3D are cross-sectional views illustrating a method of forming a stack-type semiconductor package according to example embodiments of the present inventive concept. In these example embodiments, the double-sided wiring board of FIG. 2A may be used.

Referring to FIGS. 1, 2A and 3A, the method includes preparing a lower printed circuit board (PCB) 100 having a plurality of interconnections 100a and a plurality of connection bump pads 100b formed on its upper surface. The lower printed circuit board 100 may further include lower pads 100c formed on its lower surface. One or more lower chips 106 that are sequentially stacked are mounted on the lower printed circuit board 100. Backside surfaces of the lower chips 106 may be adhered to an upper surface of the lower printed circuit board 100 through an adhesive 105. Pads of the lower chips 106 may be electrically connected to the plurality of interconnections 100a formed on the upper surface of the lower printed circuit board 100 through wires 107. Alternatively, the lower chips 106 may be electrically connected to the lower printed circuit board 100 in a flip chip configuration (i.e., using solder balls as connection terminals).

A lower molding resin compound 108 (or lower molding compound) covering the lower chips 106 may be formed on the lower printed circuit board 100 having the lower chips 106. The lower molding resin compound 108 may include an epoxy molding compound. The connection bump pads 100b may be formed so as to be exposed outside of the lower molding resin compound 108. Connection bumps 109 may be formed on the connection bump pads 100b. The connection bumps 109 may be formed in a wedge bump structure or a rounded bump structure.

External connection terminals E1 may be formed on the lower pads 100c of the lower printed circuit board 100. The external connection terminals E1 may have a ball grid array structure or a land grid array structure. The lower printed circuit board 100, the lower chips 106, and the lower molding resin compound 108 may form a lower chip package PK1.

The double-sided wiring board 110 can be pressed onto the lower chip package PK1 having the lower molding resin compound 108 using a mold P by means of heat and/or ultra sonic power TU. Here, the backing film BF serves to prevent the double-sided wiring board 110 from being damaged by physical force from the mold P. The backing film BF may be formed of a polymer material.

Referring to FIGS. 1, 2A, and 3B, the connection bumps 109 may be in contact with the lower lands 110a of the interconnection pattern I through the lower thermosetting resin layer A1. Also, the lower chip package PK1 having the lower molding resin compound 108 may be bonded to the lower thermosetting resin layer A1 by a heat process in conjunction with the pressing by the mold P. Therefore, the lower chip package PK1 and the double-sided wiring board 110 are electrically connected to each other, and are physically bonded to each other as well.

Alternatively, after the double-sided wiring board 110 is physically pressed to the lower chip package PK1 using the mold P, they may be bonded to each other by applying heat.

Referring to FIGS. 1, 2A, and 3C, the backing film BF is removed. Then, an upper chip package PK2, under which upper bumps 112 are formed, is pressed to the double-sided wiring board 110 to physically bond the upper chip package PK2 to the double-sided wiring board 110.

Formation of the upper chip package PK2 may include preparing an upper printed circuit board 111 including lower pads 111c and interconnections 111a. Then, one or more upper chips 115, which are electrically connected to the upper printed circuit board 111 and sequentially stacked, may be formed on the upper printed circuit board 111.

Backside surfaces of the upper chips 115 may be adhered to an upper surface of the upper printed circuit board 111 through adhesives 116. Then, pads of the upper chips 115 may be electrically connected to the plurality of interconnections 111a formed on the upper printed circuit board 111 through wires 117. Alternatively, the upper chips 115 may be electrically connected to the upper printed circuit board 111 in a flip chip configuration. An upper molding resin compound 120 covering the upper printed circuit board 111 having the upper chips 115 may be formed. The upper bumps 112 may be formed on the lower pads 111c. The upper bumps 112 may be formed of a material containing Sn or Au. The upper bumps 112 may be formed in a wedge bump structure or a rounded bump structure.

Referring to FIGS. 1, 2A, and 3D, as a result of bonding the upper chip package PK2 to the double-sided wiring board 110, the upper bumps 112 may be in contact with the upper lands 110b of the interconnection pattern I through the upper thermosetting resin layer A2. Heat may be applied to the double-sided wiring board 110 to bond a lower surface of the upper printed circuit board 111 of the upper chip package PK2 to the upper thermosetting resin layer A2 after the physical bonding. Accordingly, the upper chip package PK2 is electrically connected to the double-sided wiring board 110, and is physically bonded to the double-sided wiring board 110. Alternatively, the upper chip package PK2 may be physically pressed to the double-sided wiring board 110, and at the same time, heat may be applied to bond the upper chip package PK2 to the double-sided wiring board 110.

As described above, the lower chip package PK1 and the upper chip package PK2 may be electrically connected to each other through the double-sided wiring board 110, and may be physically bonded to each other. As a result, unlike in the conventional art, it is not necessary to segregate a solder ball connection region between stacked packages. Accordingly, space utilization of the lower chip package PK1 is maximized, and a molding region of the lower molding resin compound 108 is expanded, so that defects due to warpage of the lower package can be minimized.

In addition, the upper chip package PK2 is electrically connected using a wide region of the double-sided wiring board 110. Further, since bumps rather than large solder balls are used, the number of In/Out terminals can be significantly increased, so that the combination of packages having high capacity and high performance can be achieved. Also, the overall height of the package-on-package (POP) structure can be reduced.

Moreover, since the lower chip package PK1 is physically bonded to the upper chip package PK2 using the double-sided wiring board 110, the strength of the physical bond between the upper and lower packages is enhanced to improve mechanical reliability.

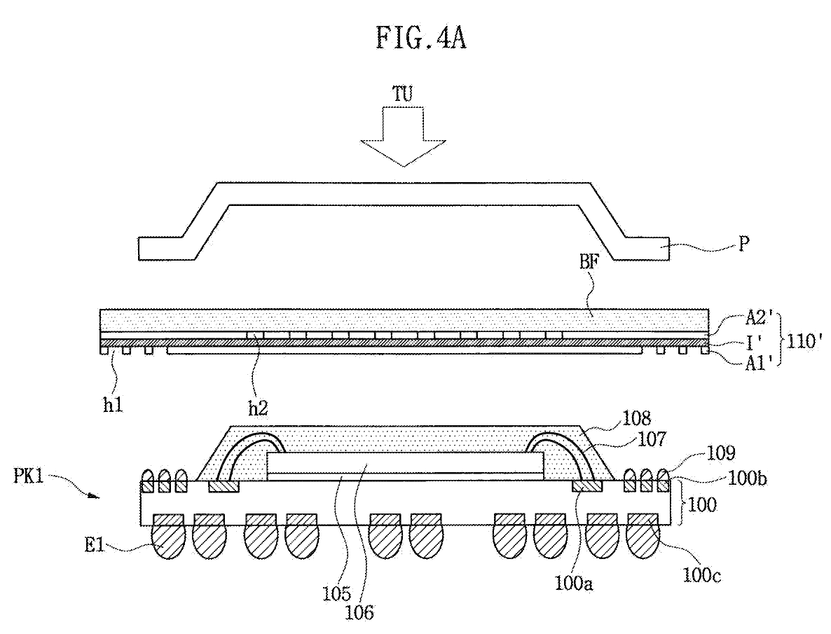

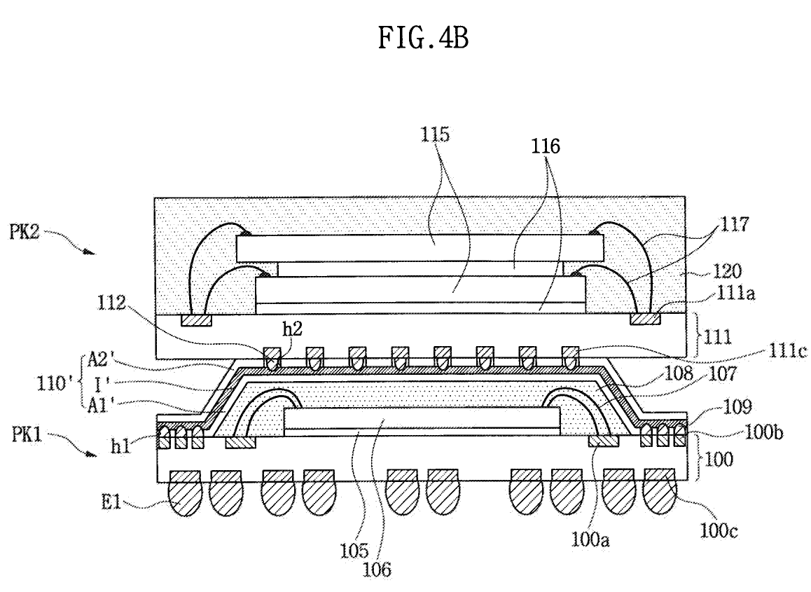

FIGS. 4A and 4B are cross-sectional views illustrating a method of forming a stack-type semiconductor package according to other example embodiments of the present inventive concept. In these example embodiments, the double-sided wiring board 110′ of FIG. 2B may be used.

Referring to FIGS. 1, 2B and 4A, the method includes preparing a lower printed circuit board 100 including a plurality of interconnections 100a and a plurality of connection bump pads 100b formed on its upper surface. The lower printed circuit board 100 may further include lower pads 100c formed on its lower surface. One or more lower chips 106 that are sequentially stacked are mounted on the lower printed circuit board 100. Backside surfaces of the lower chips 106 may be adhered to an upper surface of the lower printed circuit board 100 through an adhesive 105. Pads of the lower chips 106 may be electrically connected to the plurality of interconnections 100a formed on the upper surface of the lower printed circuit board 100 through wires 107. Alternatively, the lower chips 106 may be electrically connected to the lower printed circuit board 100 in a flip chip configuration.

A lower molding resin compound 108 covering the lower chips 106 may be formed on the lower printed circuit board 100 having the lower chips 106. The lower molding resin compound 108 may include an epoxy molding compound. The connection bump pads 100b may be formed so as to be exposed outside of the lower molding resin compound. Connection bumps 109 may be formed on the connection bump pads 100b. The connection bumps 109 may be formed in a wedge bump structure or a rounded bump structure.

External connection terminals E1 may be formed on the lower pads 100c of the lower printed circuit board 100. The external connection terminals E1 may have a ball grid array structure or a land grid array structure. The lower printed circuit board 100, the lower chips 106, and the lower molding resin compound 108 may form a lower chip package PK1.

The double-sided wiring board 110′ is pressed and bonded to the lower chip package PK1 having the lower molding resin compound 108 using a mold P by means of heat and/or ultrasonic power TU. Here, a backing film BF serves to prevent the double-sided wiring board 110′ from being damaged by physical force from the mold. The backing film BF may be formed of a polymer material.

Referring to FIGS. 1, 2A and 4B, as a result of the pressing with the mold P, the connection bumps 109 may be in contact with lower lands 110a of an interconnection pattern I′ through lower via holes h1 of a lower thermosetting resin layer A1′. Also, the board having the lower molding resin compound 108 may be bonded to the lower thermosetting resin layer A1′ by heat. Therefore, the lower chip package PK1 may be electrically connected to the double-sided wiring board 110′, and physically bonded to the double-sided wiring board 110′ as well.

The backing film BF is removed. Then, the upper chip package PK2, under which upper bumps 112 are formed, is pressed and bonded to the double-sided wiring board 110′. The upper chip package PK2 may be formed by a similar method to that described above with reference to FIG. 3C.

As a result, the upper bumps 112 may be in contact with the upper lands 110b of the interconnection pattern I′ through upper via holes h2 of an upper thermosetting resin layer A2′. Heat may be applied sequentially to the double-sided wiring board 110′ to bond a lower surface of the upper printed circuit board 111 of the upper chip package PK2 to the upper thermosetting resin layer A2′. Accordingly, the upper chip package PK2 and the double-sided wiring board 110′ are electrically connected to each other, and physically bonded to each other as well. Alternatively, the upper chip package PK2 may be pressed to the double-sided wiring board 110′, and at the same time, heat may be applied to bond them.

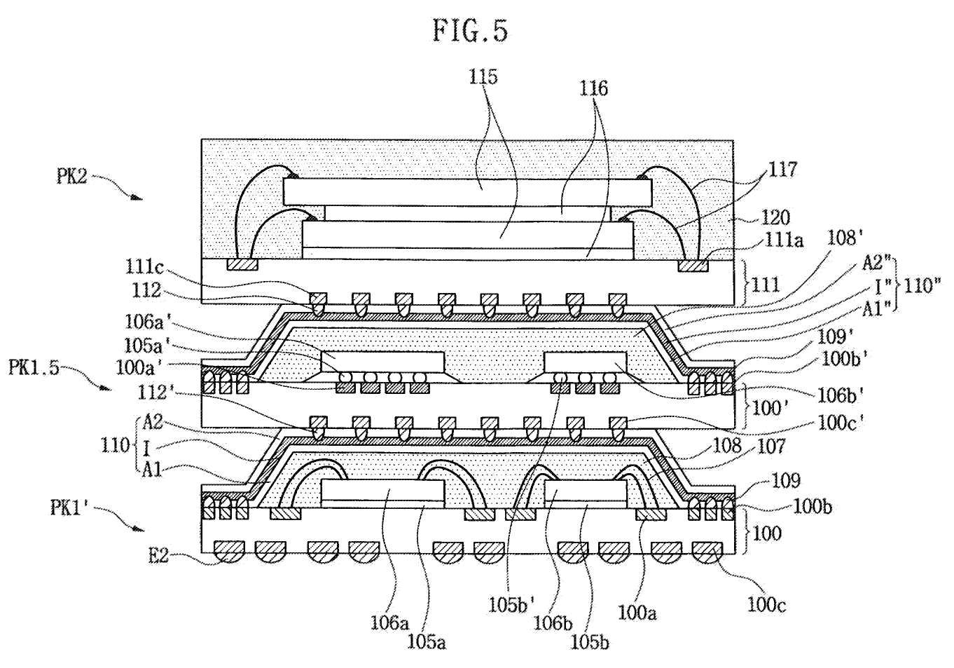

FIG. 5 is a cross-sectional view illustrating a method of forming a stack-type semiconductor package according to still other example embodiments of the present inventive concept. In these example embodiments, the double-sided wiring board of FIG. 2A may be used.

Referring to FIGS. 1, 2B and 5, still other example embodiments of the present inventive concept may further include stacking one or more intermediate chip packages PK1.5 between a lower chip package PK1′ and an upper chip package PK2 using an intermediate double-sided wiring board 110″.

Specifically, the method includes preparing a lower printed circuit board 100 including a plurality of interconnections 100a and a plurality of connection bump pads 100b formed on its upper surface. The lower printed circuit board 100 may further include lower pads 100c formed on its lower surface. One or more first lower chips 106a that are sequentially stacked are mounted on the lower printed circuit board 100. Backside surfaces of the first lower chips 106a may be adhered to an upper surface of the lower printed circuit board 100 through an adhesive 105a. One or more second lower chips 106b, which are aligned parallel to the first lower chips 106a, and sequentially stacked, are mounted on the lower printed circuit board 100. Backside surfaces of the second lower chips 106b may be adhered to an upper surface of the lower printed circuit board 100 through an adhesive 105b.

Then, pads of the first and second lower chips 106a and 105b may be electrically connected to the plurality of interconnections 100a formed on the upper surface of the lower printed circuit board 100 through wires 107. Alternatively, the first and second lower chips 106a and 105b may be electrically connected to the lower printed circuit board 100 in a flip chip configuration.

A lower molding resin compound 108 covering the first and second lower chips 106a and 106b may be formed on the lower printed circuit board 110 having the first and second lower chips 106a and 106b. The lower molding resin compound 108 may include an epoxy molding compound. The connection bump pads 100b may be formed so as to be exposed outside of the lower molding resin compound 108. Connection bumps 109 may be formed on the connection bump pads 100b. The connection bumps 109 may be formed in a wedge bump structure or a rounded bump structure.

External connection terminals E2 may be formed on the lower pads 100c of the lower printed circuit board 100. As illustrated, the external connection terminals E2 may be formed in a land grid array structure. In this case, the overall height of a POP structure can be reduced. Alternatively, the external connection terminals may be formed in a ball grid array structure. The lower printed circuit board 100, the first and second lower chips 106a and 106b, and the lower molding resin compound 108 may form a lower chip package PK1′.

A similar process to that described above with respect to FIG. 3A is performed to press and bond the double-sided wiring board 110 to the lower chip package PK1′ having the lower molding resin compound 108 using heat or ultrasonic power. As a result, the connection bumps 109 may be in contact with lower lands 110a of an interconnection pattern I through the lower thermosetting resin layer A1. Also, the lower chip package PK1′ may be bonded to the lower thermosetting resin layer A1 by the heat. Therefore, the lower chip package PK1′ and the double-sided wiring board 110 are electrically connected to each other, and physically bonded to each other as well.

Next, an intermediate chip package PK1.5, under which intermediate bumps 112′ are formed, is pressed and bonded to the double-sided wiring board 110. The intermediate chip package PK1.5 includes an intermediate printed circuit board 100′ including a plurality of interconnections 100a′, and a plurality of connection bump pads 100b′ formed on its upper surface. The intermediate printed circuit board 100′ may further include lower pads 100c′ formed on its lower surface. One or more first intermediate chips 106a′ that are sequentially stacked are mounted on the intermediate printed circuit board 100′. The first intermediate chips 106a′ may be in contact with the plurality of interconnections 100a′ of the intermediate printed circuit board 100′ in a flip chip configuration using flip chip connection terminals 105a′. One or more second intermediate chips 106b′, which are aligned parallel to the first intermediate chips 106a′, and sequentially stacked, are disposed on the intermediate printed circuit board 100′. The second intermediate chips 106b′ may be in contact with the plurality of interconnections 100a′ of the intermediate printed circuit board 100′ in a flip chip configuration using flip chip connection terminals 105b′. Alternatively, the first and second intermediate chips 106a′ and 106b′ may be electrically connected to the intermediate printed circuit board 100′ using a wire bonding configuration.

An intermediate molding resin compound 108′ covering the first and second intermediate chips 106a′ and 106b′ may be formed on the intermediate printed circuit board 100′ having the first and second intermediate chips 106a′ and 106b′. The intermediate molding resin compound 108′ may include an epoxy molding compound. The connection bump pads 100b′ may be formed so as to be exposed outside of the intermediate molding resin compound 108′. Connection bumps 109′ may be formed on the connection bump pads 100b′. The connection bumps 109′ may be formed in a wedge bump structure or a rounded bump structure. The intermediate bumps 112′ may be formed on the lower pads 100c′ of the intermediate printed circuit board 100′. The intermediate bumps 112′ may be formed in a wedge bump structure or a rounded bump structure.

As a result of bonding the intermediate chip packages PK1.5 to the double-sided wiring board 110, the intermediate bumps 112′ may be in contact with the upper lands 110b of the interconnection pattern I through an upper thermosetting resin layer A2. Then, heat may be applied to the double-sided wiring board 110 to bond a lower surface of the intermediate printed circuit board 100′ of the intermediate chip package PK1.5 to the upper thermosetting resin layer A2. Accordingly, the intermediate chip package PK1.5 and the double-sided wiring board 110 are electrically connected to each other, and physically bonded to each other as well. Alternatively, the intermediate chip package PK1.5 may be physically pressed to the double-sided wiring board 110, and at the same time, heat may be applied to bond them.

Subsequently, a similar process to that described above with respect to FIG. 3A is performed to bond an intermediate double-sided wiring board 110″ to the intermediate printed circuit board 100′ having the lower molding resin compound 108′ using heat or ultrasonic power. As a result, the connection bumps 109′ may be in contact with lower lands 110a of an interconnection pattern I″ through a lower thermosetting resin layer A1″. Also, the intermediate printed circuit board 100′ having the lower molding resin compound 108′ may be bonded to the lower thermosetting resin layer A1″ by the heat. Therefore, the intermediate chip package PK1.5 and the intermediate double-sided wiring board 110′ may be electrically connected to and physically bonded to each other.

An upper chip package PK2, under which upper bumps 112 are formed, is bonded to the intermediate double-sided wiring board 110″. The upper chip package PK2 may be formed by a similar method to that described above with respect to FIG. 3C.

As a result, the upper bumps 112 may be in contact with the upper lands 110b of the interconnection pattern I″ through the upper thermosetting resin layer A2″. Heat may be applied sequentially to the intermediate double-sided wiring board 110″ to bond a lower surface of the upper printed circuit board 111 of the upper chip package PK2 to the upper thermosetting resin layer A2″. Accordingly, the upper chip package PK2 and the intermediate double-sided wiring board 110″ are electrically connected to each other, and physically bonded to each other as well.

As described above, the lower chip package PK1, the intermediate chip package PK1.5, and the upper chip package PK2 may be electrically connected to each other through the double-sided wiring board 110 and the intermediate double-sided wiring board 110″, and may be physically bonded to each other as well. As a result, it is not necessary to segregate a solder ball connection region, unlike in the conventional art. Thus, the space utilization of the lower chip package PK1 and the intermediate chip package PK1.5 can be maximized to two-dimensionally align the first and second lower chips. Therefore, the overall height of the POP structure can be reduced.

Furthermore, the chip packages PK1, PK1.5 and PK2 are physically bonded to each other using the double-sided wiring board 110 and the intermediate double-sided wiring board 110″, so that the strength of the bond between the upper and lower packages is enhanced to improve mechanical reliability.

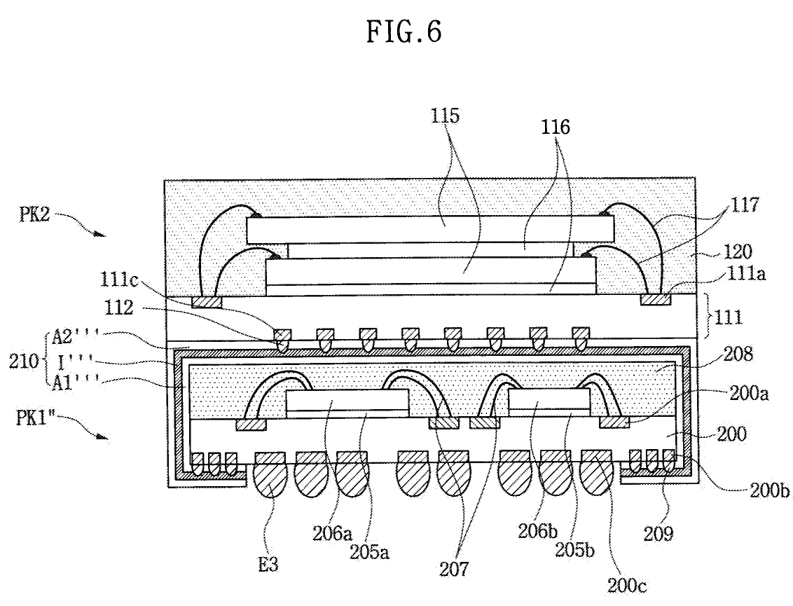

FIG. 6 is a cross-sectional view illustrating a method of forming a stack-type semiconductor package according to yet other example embodiments of the present inventive concept. In these example embodiments, the double-sided wiring board of FIG. 2A may be used.

Referring to FIGS. 1, 2A and 6, this method includes preparing a lower printed circuit board 200 including a plurality of interconnections 200a formed on its upper surface. The lower printed circuit board 200 may further include connection bump pads 200b and lower pads 200c formed on its lower surface. One or more first lower chips 206a that are sequentially stacked are mounted on the lower printed circuit board 200. Backside surfaces of the first lower chips 206a may be adhered to an upper surface of the lower printed circuit board 200 through an adhesive 205a. One or more second lower chips 206b, which are aligned parallel to the first lower chips 206a, and sequentially stacked, are mounted on the lower printed circuit board 200. Backside surfaces of the second lower chips 206b may be adhered to an upper surface of the lower printed circuit board 200 through an adhesive 205b.

Pads of the first and second lower chips 206a and 206b may be electrically connected to the plurality of interconnections 200a formed on the upper surface of the lower printed circuit board 200 through wires 207. Alternatively, the first and second lower chips 206a and 206b may be electrically connected to the lower printed circuit board 200 in a flip chip configuration.

A lower molding resin compound 208 covering the first and second lower chips 206a and 206b may be formed on the lower printed circuit board 200 having the first and second lower chips 206a and 206b. The lower molding resin compound 208 may include an epoxy molding compound. The lower molding resin compound 208 may be formed to cover the entire upper surface of the lower printed circuit board 200. Then, connection bumps 209 may be formed on the connection bump pads 200b. The connection bumps 209 may be formed in a wedge bump structure or a rounded bump structure.

External connection terminals E3 may be formed on the lower pads 200c of the lower printed circuit board 200. As illustrated, the external connection terminals E3 may be formed in a ball grid array structure. Alternatively, they may be formed in a land grid array structure. In the case of the land grid array structure, the overall height of a POP structure may be reduced. The lower printed circuit board 200, the first and second lower chips 206a and 206b, and the lower molding resin compound 208 may form a lower chip package PK1″.

Next, the double-sided wiring board 210 is bonded to the lower chip package PK1″ having the lower molding resin compound 208 using heat or ultrasonic power. Here, the double-sided wiring board 210 is formed so as to surround an edge region of a lower surface of the lower printed circuit board 200. That is, the double-sided wiring board 210 extends to the connection bumps 209 so as to surround the lower printed circuit board 200. As a result, the connection bumps 209 may be in contact with lower lands 110a of an interconnection pattern I′″ through a lower thermosetting resin layer A1′″. Also, the board having the lower molding resin compound 208 may be bonded to the lower thermosetting resin layer A1.′″ by heat. Therefore, the lower chip package PK1″ and the double-sided wiring board 210 are electrically connected to each other, and physically bonded to each other as well.

Sequentially, the upper chip package PK2, under which the upper bumps 112 are formed, is pressed to the double-sided wiring board 210, and heat is applied for curing. The upper bumps 112 may be in contact with upper lands 110b of the interconnection pattern I′″ through an upper thermosetting resin layer A2′″. Therefore, the lower chip package PK1″ and the double-sided wiring board 210 are electrically connected to each other, and physically bonded to each other as well.

A stack-type semiconductor package according to example embodiments of the present inventive concept will be described with reference again to FIGS. 1, 2A and 3D.

Referring to FIGS. 1, 2A and 3D, the stack-type semiconductor package includes a lower printed circuit board 100 having a plurality of interconnections 100a and a plurality of connection bump pads 100b formed on its upper surface. The lower printed circuit board 100 may further include lower pads 100c formed on its lower surface. One or more lower chips 106 that are sequentially stacked are disposed on the lower printed circuit board 100. Backside surfaces of the lower chips 106 may be adhered to an upper surface of the lower printed circuit board 100 through an adhesive 105. Also, pads of the lower chips 106 may be electrically connected to the plurality of interconnections 100a formed on the upper surface of the lower printed circuit board 100 through wires 107. Alternatively, the lower chips 106 may be electrically connected to the lower printed circuit board 100 in a flip chip configuration.

A lower molding resin compound 108 covering the lower chips 106 may be disposed on the lower printed circuit board 100 having the lower chips 106. The lower molding resin compound 108 may include an epoxy molding compound. The connection bump pads 100b may be formed so as to be exposed outside of the lower molding resin compound 108. Connection bumps 109 may be in contact with the connection bump pads 100b. The connection bumps 109 may be formed in a wedge bump structure or a rounded bump structure.

External connection terminals E1 may be disposed on the lower pads 100c of the lower printed circuit board 100. The external connection terminals E1 may include a ball grid array structure or a land grid array structure. The lower printed circuit board 100, the lower chips 106, and the lower molding resin compound 108 may form a lower chip package PK1.

The double-sided wiring board 110 is bonded to the lower chip package PK1 having the lower molding resin compound 108. The connection bumps 109 may pass through the lower thermosetting resin layer A1 to be in contact with lower lands 110a of an interconnection pattern I. Therefore, the lower chip package PK1 and the double-sided wiring board 110 may be electrically connected to each other, and may be physically bonded to each other as well.

The upper chip package PK2, under which upper bumps 112 are formed, is bonded to the double-sided wiring board 110 so as to be disposed thereon. The upper chip package PK2 includes an upper printed circuit board 111 including lower pads 111c and interconnections 111a. One or more upper chips 115, which are electrically connected to the upper printed circuit board 111 and sequentially stacked, are disposed on the upper printed circuit board 111. Backside surfaces of the upper chips 115 may be adhered to an upper surface of the upper printed circuit board 111 through adhesives 116. Pads of the upper chips 115 may be electrically connected to the plurality of interconnections 111a formed on the upper surface of the upper printed circuit board 111 through wires 117. Alternatively, the upper chips 115 may be electrically connected to the upper printed circuit board 111 in a flip chip configuration.

An upper molding resin compound 120 covering the upper printed circuit board 111 having the upper chips 115 may be provided. Upper bumps 112 that are in contact with the lower pads 111c, respectively, may also be provided. The upper bumps 112 may be formed of a material containing Sn or Au. The upper bumps 112 may be formed in a wedge bump structure or a rounded bump structure.

The upper bumps 112 may be in contact with the upper lands 110b of the interconnection pattern I through the upper thermosetting resin layer A2. Therefore, the upper chip package PK2 and the double-sided wiring board 110 may be electrically connected to each other, and may be physically bonded to each other as well.

Alternatively, as illustrated in FIGS. 1, 2B, and 4B, the double-sided wiring board 110′ may include a lower thermosetting resin layer A1′, an interconnection pattern I′, and an upper thermosetting resin layer A2′, which are sequentially stacked. Also, the lower thermosetting resin layer A1′ may expose the lower connection lands 110a through lower via holes h1, and the upper thermosetting resin layer A2′ may expose the upper connection lands 110b through upper via holes h2. Therefore, the connection bumps 109 may be in contact with the lower connection lands 110a through the lower via holes h1 of the lower thermosetting resin layer A1′, and the upper bumps 112 may be in contact with the upper connection lands 110b through the upper via holes h2 of the upper thermosetting resin layer A2′.

As described above, the lower chip package PK1 and the upper chip package PK2 may be electrically connected to each other through the double-sided wiring board 110, and may be physically bonded to each other as well. As a result, unlike in the conventional art, it is not necessary to segregate a solder ball connection region. Thus, space utilization of the lower chip package PK1 is maximized, and a molding region of the lower molding resin compound 108 is expanded, so that defects due to warpage of the lower package can be minimized.

In addition, the upper chip package PK2 is electrically connected using a wide region of the double-sided wiring board 110. Further, since bumps rather than large solder balls are used, the number of In/Out terminals can be significantly increased, so that a combination of packages of high capacity and high performance can be achieved. Also, the overall height of the POP structure can be reduced.

Moreover, since the lower chip package PK1 is physically bonded to the upper chip package PK2 using the double-sided wiring board 110, the strength of the physical bond between the upper and lower packages is enhanced to improve mechanical reliability.

A stack-type semiconductor package according to other example embodiments of the present inventive concept will be described with reference again to FIGS. 1, 2A and 5.

Referring to FIGS. 1, 2A and 5, the stack-type semiconductor package further includes one or more intermediate chip packages PK1.5, which are stacked between a lower chip package PK1′ and an upper chip package PK2 through an intermediate double-sided wiring board 110″.

Specifically, in the stack-type semiconductor package, the lower chip package PK1′ includes a lower printed circuit board 100 including a plurality of interconnections 100a and a plurality of connection bump pads 100b formed on its upper surface. The lower printed circuit board 100 may further include lower pads 100c formed on its lower surface. One or more first lower chips 106a that are sequentially stacked are disposed on the lower printed circuit board 100. Backside surfaces of the first lower chips 106a may be adhered to an upper surface of the lower printed circuit board 100 through an adhesive 105a. One or more second lower chips 106b, which are aligned parallel to the first lower chips 106a and sequentially stacked, are disposed on the lower printed circuit board 100. Backside surfaces of the second lower chips 106b may be adhered to the upper surface of the lower printed circuit board 100 through an adhesive 105b.

The pads of the first and second lower chips 106a and 106b may be electrically connected to the plurality of interconnections 100a formed on the upper surface of the lower printed circuit board 100 through wires 107. Alternatively, the first and second lower chips 106a and 106b may be electrically connected to the lower printed circuit board 100 in a flip chip configuration.

A lower molding resin compound 108 covering the first and second lower chips 106a and 106b may be disposed on the lower printed circuit board 100 having the first and second lower chips 106a and 106b. The lower molding resin compound 108 may include an epoxy molding compound. The connection bump pads 100b may be exposed outside of the lower molding resin compound 108. Connection bumps 109 may be formed in contact with the connection bump pads 100b. The connection bumps 109 may be formed in a wedge bump structure or a rounded bump structure.

External connection terminals E2 may be disposed on the lower pads 100c of the lower printed circuit board 100. As illustrated in FIG. 5, the external connection terminals E2 may be formed in a land grid array structure. In the case of the land grid array (E2) structure, the overall height of a POP structure can be reduced. Alternatively, the electrodes may be formed in a ball grid array structure. The lower printed circuit board 100, the first and second lower chips 106a and 106b, and the lower molding resin compound 108 may form a lower chip package PK1′.

The double-sided wiring board 110 is bonded to the board having the lower molding resin compound 108. The connection bumps 109 may be in contact with lower lands 110a of an interconnection pattern I through a lower thermosetting resin layer A1. Therefore, the lower chip package PK1′ and the double-sided wiring board 110 may be electrically connected to each other, and physically bonded to each other as well.

An intermediate chip package PK1.5, under which intermediate bumps 112′ are formed, is bonded to the double-sided wiring board 110. The intermediate bumps 112′ may be in contact with the upper lands 110b of the interconnection pattern I through an upper thermosetting resin layer A2. Therefore, the intermediate chip package PK1.5 and the double-sided wiring board 110 may be electrically connected to each other, and physically bonded to each other as well.

The intermediate chip package PK1.5 includes an intermediate printed circuit board 100′ including a plurality of interconnections 100a′ and a plurality of connection bump pads 100b′ formed on its upper surface. The intermediate printed circuit board 100′ may further include lower pads 100c′ formed on its lower surface. One or more first intermediate chips 106a′, which are sequentially stacked, are disposed on the intermediate printed circuit board 100′. The first intermediate chips 106a′ may be in contact with the plurality of interconnections 100a′ of the intermediate printed circuit board 100′ using flip chip connection terminals 105a′. One or more second intermediate chips 106b′, which are aligned parallel to the first intermediate chips 106a′ and sequentially stacked, are mounted on the intermediate printed circuit board 100′. The second intermediate chips 106b′ may be in contact with the plurality of interconnections 100a′ of the intermediate printed circuit board 100′ using flip chip connection terminals 105b′. Alternatively, the first and second intermediate chips 106a′ and 106b′ may be electrically connected to the intermediate printed circuit board 100′ using a wire bonding configuration.

An intermediate molding resin compound 108′ covering the first and second intermediate chips 106a′ and 106b′ may be disposed on the intermediate printed circuit board 100′ having the first and second intermediate chips 106a′ and 106b′. The intermediate molding resin compound 108′ may include an epoxy molding compound. The connection bump pads 100b′ may be exposed outside of the intermediate molding resin compound 108′. Connection bumps 109′ may be formed on the connection bump pads 100b′. The connection bumps 109′ may be formed in a wedge bump structure or a rounded bump structure. The intermediate bumps 112′ may be disposed on the lower pads 100c′ of the intermediate printed circuit board 100′. The intermediate bumps 112′ may be formed in a wedge bump structure or a rounded bump structure.

The intermediate double-sided wiring board 110″ is bonded to the intermediate printed circuit board 100′ having the intermediate molding resin compound 108′. The connection bumps 109″ may be in contact with lower lands 110a of an interconnection pattern I″ through a lower thermosetting resin layer A1′. Therefore, the intermediate chip package PK1.5 and the intermediate double-sided wiring board 110′ are electrically connected to each other, and physically bonded to each other as well.

An upper chip package PK2, under which upper bumps 112 are mounted, is bonded to the intermediate double-sided wiring board 110′. The upper bumps 112 may be in contact with the upper lands 110b of the interconnection pattern I″ through the upper thermosetting resin layer A2″. Accordingly, the upper chip package PK2 and the intermediate double-sided wiring board 110″ are electrically connected to each other, and physically bonded to each other as well.

As described above, the lower chip package PK1, the intermediate chip package PK1.5, and the upper chip package PK2 may be electrically connected to each other through the double-sided wiring board 110 and the intermediate double-sided wiring board 110″, and may be physically bonded to each other as well. As a result, it is not necessary to segregate a solder ball connection region, unlike in the conventional art. Accordingly, space utilization of the lower chip package PK1 and the intermediate chip package PK1.5 can be maximized to two-dimensionally align the first and second lower chips. Therefore, the overall height of the POP structure can be reduced.

Furthermore, the chip packages PK1, PK1.5 and PK2 are physically bonded to each other using the double-sided wiring board 110 and the intermediate double-sided wiring board 110″, so that the strength of the physical bond between the upper, intermediate, and lower packages is enhanced to improve mechanical reliability.

A stack-type semiconductor package according to still other example embodiments of the present inventive concept will be described with reference again to FIGS. 1, 2A and 6.

Referring to FIGS. 1, 2A and 6, the stack-type semiconductor package includes a lower printed circuit board 200 including a plurality of interconnections 200a formed on its upper surface. The lower printed circuit board 200 may further include connection bump pads 200b and lower pads 200c formed on its lower surface. One or more first lower chips 206a, which are sequentially stacked, are disposed on the lower printed circuit board 200. Backside surfaces of the first lower chips 206a may be adhered to an upper surface of the lower printed circuit board 200 through an adhesive 205a. One or more second lower chips 206b, which are aligned parallel to the first lower chips 206a and sequentially stacked, are disposed on the lower printed circuit board 200. Backside surfaces of the second lower chips 206b may be adhered to an upper surface of the lower printed circuit board 200 through an adhesive 205b.

Pads of the first and second lower chips 206a and 206b may be electrically connected to the plurality of interconnections 200a formed on the upper surface of the lower printed circuit board 200 through wires 207. Alternatively, the first and second lower chips 206a and 206b may be electrically connected to the lower printed circuit board 200 in a flip chip configuration.

A lower molding resin compound 208 covering the first and second lower chips 206a and 206b may be disposed on the lower printed circuit board 200 having the first and second lower chips 206a and 206b. The lower molding resin compound 208 may include an epoxy molding compound. The lower molding resin compound 208 may be disposed to cover the entire surface of the lower printed circuit board 200. Connection bumps 209 may be disposed to be in contact with the connection bump pads 200b. The connection bumps 209 may be formed in a wedge bump structure or a rounded bump structure.

External connection terminals E3 may be disposed on the lower pads 200c of the lower printed circuit board 200. As illustrated, the external connection terminals E3 may be formed in a ball grid array structure. Alternatively, the external connection terminals E3 may be formed in a land grid array structure. In the case of the land grid array structure, the overall height of a POP structure can be reduced. The lower printed circuit board 200, the first and second lower chips 206a and 206b, and the lower molding resin compound 208 may form a lower chip package PK1″.

The double-sided wiring board 210 may be bonded to the board having the lower molding resin compound 208. Here, the double-sided wiring board 210 is formed to surround an edge region of a lower surface of the lower printed circuit board 200. That is, the double-sided wiring board 210 extends to the connection bumps 209 to surround the lower printed circuit board. As a result, the connection bumps 209 may be in contact with lower lands 110a of an interconnection pattern I′″ through a lower thermosetting resin layer A1′″. Therefore, the lower chip package PK1″ and the double-sided wiring board 210 are electrically connected to each other and physically bonded to each other as well.

An upper chip package PK2, under which upper bumps 112 are formed, is bonded to the double-sided wiring board 210. The upper bumps 112 may be in contact with upper lands 110b of the interconnection pattern I′″ through an upper thermosetting resin layer A2′″. Therefore, the upper chip package PK1″ and the upper chip package are electrically connected to each other through the double-sided wiring board 210, and are physically bonded to each other as well.

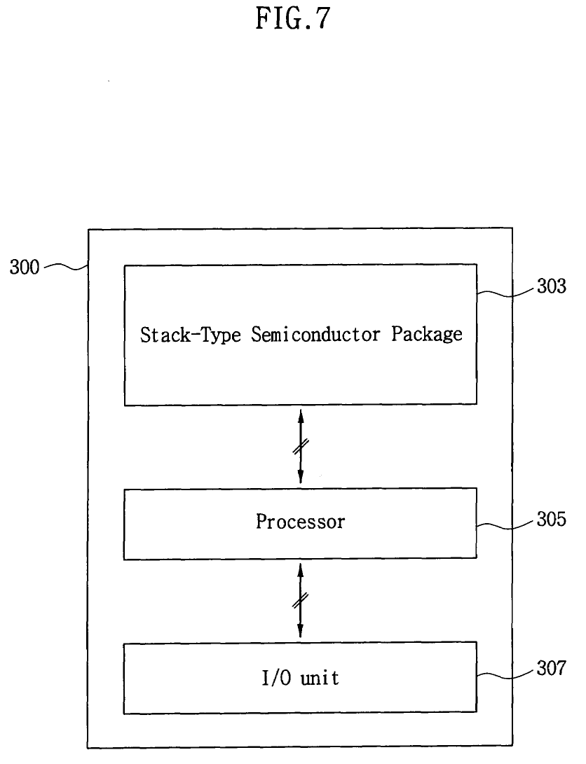

FIG. 7 is a schematic block diagram of an electronic system including a stack-type semiconductor package according to example embodiments of the present inventive concept.

Referring to FIG. 7, the electronic system 300 includes one or more stack-type semiconductor packages 303 and a processor 305 connected to the stack-type semiconductor packages 303. Here, the stack-type semiconductor packages 303 may include a stack-type semiconductor package as described above with reference to any of FIGS. 3D, 4B, 5 and 6. For example, as illustrated in FIG. 5, the stack-type semiconductor package 303 can include a lower chip package PK1′, an intermediate chip package PK1.5, and an upper chip package PK2 physically bonded to each other through a double-sided wiring board 110 and an intermediate double-sided wiring board 110″, and electrically connected to each other as well. The lower chip package PK1′ may be a logic package, and the intermediate chip package PK1.5 and the upper chip package PK2 may be memory packages.

The electronic system 300 may correspond to a portion of a notebook computer, a digital camera, a music player (MP3), or a cellular phone. In this case, the processor 305 and the stack-type semiconductor package 303 may be installed on a board, and the stack-type semiconductor package 303 may function as a data storage medium for the processor 305.

The electronic system 300 may exchange data with other electronic systems such as personal computers or computer networks through an input/output unit 307. The input/output unit 307 may provide data through a peripheral bus line of a computer, a high-speed digital transmission line or a wireless transmission/reception antenna. The data communication between the processor 305 and the stack-type semiconductor package 303, and the data communication between the processor 305 and the input/output unit 307 may be performed using general bus architectures.

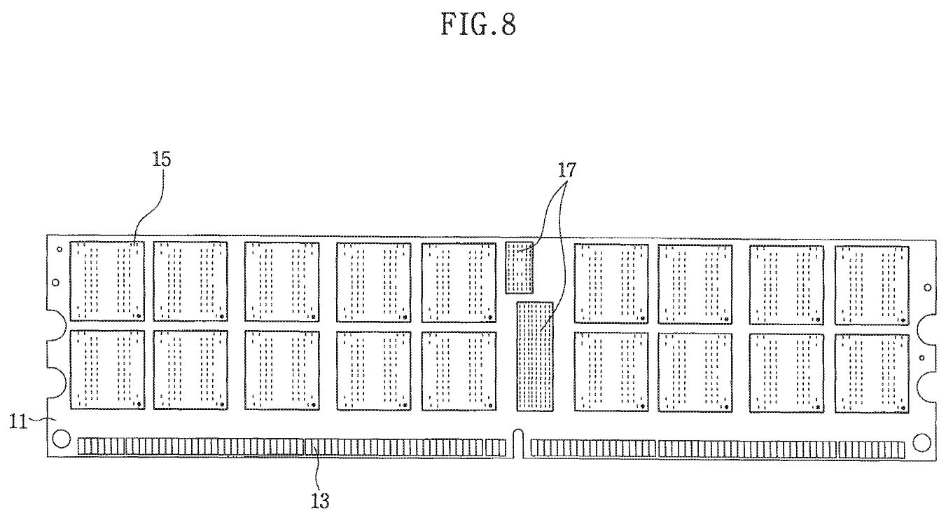

FIG. 8 is a schematic diagram of a memory module, in which a stack-type semiconductor package is mounted, according to example embodiments of the present inventive concept.

Referring to FIG. 8, the memory module includes a board body 11 including a plurality of tabs 13 and stack-type semiconductor packages 15, which are mounted on the board body 11 in an array of two columns or more. Here, the stack-type semiconductor package 15 may include a stack-type semiconductor package as described above with reference to any of FIGS. 3D, 4B, 5 and 6. For example, as illustrated in FIG. 5, the stack-type semiconductor package 15 can include a lower chip package PK1′, an intermediate chip package PK1.5, and an upper chip package PK2 physically bonded to each other through a double-sided wiring board 110 and an intermediate double-sided wiring board 110″, and electrically connected to each other as well. The lower chip package PK1′ may be a logic package, and the intermediate chip package PK1.5 and the upper chip package PK2 may be memory packages.

Discrete devices 17 may be mounted on the board body 11. The discrete devices 17 may include at least one selected from the group consisting of a register, a capacitor, an inductor, a resistor, a programmable device, and a non-volatile memory device.

The memory module may be adapted as a data storage device for a plurality of electronic systems such as personal computers, system servers, and communication devices. The memory module may be electrically connected to an external connector through the tabs 13 mounted on the board body 11.

According to the present inventive concept, a lower chip package and an upper chip package can be electrically connected to each other through a double-sided wiring board, and also can be physically bonded to each other. As a result, unlike in the conventional art, it is not necessary to segregate a solder ball connection region. Accordingly, space utilization of the lower chip package can be maximized to two-dimensionally align lower chips. In addition, a molding region of the lower molding resin compound is increased to prevent defects due to warpage of a lower package.

Further, the upper chip package is electrically connected using a large region of the double-sided wiring board, and a bump is used rather than a large solder ball, so that the number of In/Out terminals can be considerably increased to enable high performance packages to be combined, and overall height of a POP structure to be reduced.

Moreover, the lower chip package and the upper chip package are physically bonded to each other using the double-sided wiring board to improve the strength of the physical bond between the upper and lower packages, so that mechanical reliability can be enhanced.

In one aspect, the present inventive concept is directed to a stack-type semiconductor package. The stack-type semiconductor package includes a lower printed circuit board having a plurality of interconnections and a plurality of connection bumps. One or more first lower chips, which are electrically connected to the plurality of interconnections and sequentially stacked, are disposed on the lower printed circuit board. A lower molding resin compound is disposed on the lower printed circuit board to cover the first lower chips. A double-sided wiring board, which is bonded to the lower molding resin compound and is electrically connected to the connection bumps, is disposed on the lower molding resin compound. An upper chip package, which includes upper bumps electrically connected to an interconnection pattern of the double-sided wiring board and is bonded to the double-sided wiring board, is disposed on the double-sided wiring board.

In some example embodiments of the present inventive concept, the upper chip package may include an upper printed circuit board including lower pads. One or more upper chips, which are electrically connected to the upper printed circuit board and sequentially stacked, may be disposed on the upper printed circuit board. An upper molding resin compound covering the upper printed circuit board having the upper chips may be provided. The upper bumps may be in contact with the lower pads.

In other example embodiments, the lower printed circuit board, the first lower chips, and the lower molding resin compound may form a lower chip package.

In still other example embodiments, the stack-type semiconductor package may further include one or more intermediate chip packages disposed between the lower chip package and the upper chip package. Here, the intermediate chip package and the upper chip package may be physically bonded to each other through an intermediate double-sided wiring board and electrically connected to each other as well.

In yet other example embodiments, external connection terminals disposed under the lower printed circuit board may be further included. Here, the external connection terminals may be formed in a ball grid array structure or a land grid array structure.

In yet other example embodiments, the double-sided wiring board may include a lower thermosetting resin layer, the interconnection pattern, and an upper thermosetting resin layer, which are sequentially stacked.

In still other example embodiments, the connection bumps may be in contact with the interconnection pattern through the lower thermosetting resin layer.

In yet other example embodiments, the upper bumps may be in contact with the interconnection pattern through the upper thermosetting resin layer.

In still other example embodiments, the stack-type semiconductor package may further include one or more second lower chips, which are disposed parallel to the first lower chips and sequentially stacked, disposed on the lower printed circuit board. Here, the second lower chips may be covered with the lower molding resin compound.

In yet other example embodiments, the connection bumps may be disposed on the lower printed circuit board so as to be disposed around the lower molding resin compound.

In still other example embodiments, the connection bumps may be disposed at an edge region of a lower surface of the lower printed circuit board, wherein the double-sided wiring board may extend to surround the edge region of the lower surface of the lower printed circuit board having the lower molding resin compound, so that the connection bumps may be electrically connected to the double-sided wiring board.

In another aspect, the present inventive concept is directed to a method of forming a stack-type semiconductor package. The method includes preparing a lower printed circuit board including a plurality of interconnections and a plurality of connection bump pads. One or more first lower chips, which are electrically connected to the plurality of interconnections and sequentially stacked, are mounted on the lower printed circuit board. A lower molding resin compound is formed on the lower printed circuit board to cover the first lower chips. Connection bumps that are in contact with the connection bump pads are formed. A double-sided wiring board is bonded to cover the lower printed circuit board having the lower molding resin compound and to be electrically connected to the connection bumps. An upper chip package including upper bumps is bonded to the double-sided wiring board, wherein the upper bumps are formed to be electrically connected to an interconnection pattern of the double-sided wiring board.

In some example embodiments of the present inventive concept, the double-sided wiring board may be formed to include a lower thermosetting resin layer, the interconnection pattern, and an upper thermosetting resin layer, which are sequentially stacked.

In other example embodiments, bonding the double-sided wiring board to cover the lower printed circuit board having the lower molding resin compound and to be electrically connected to the connection bumps may include: adhering a backing film onto the upper thermosetting resin layer of the double-sided wiring board; bonding using heat or ultrasonic power by means of a pressing mold, so that the connection bumps are in contact with the interconnection pattern through the lower thermosetting resin layer; and removing the backing film.

In still other example embodiments, bonding the upper chip package including upper bumps to the double-sided wiring board may include: physically pressing the upper chip package so that the upper bumps may be in contact with the interconnection pattern through the upper thermosetting resin layer; and applying heat to the double-sided wiring board so that the upper thermosetting resin layer may be bonded to the upper chip package.

In yet other example embodiments, the method may further include patterning the upper and lower thermosetting resin layers to expose lands of the interconnection pattern by via holes before bonding the double-sided wiring board to cover the board having the lower molding resin compound and to be electrically connected to the connection bumps. Here, the via holes may be disposed to be aligned with the bumps.

In still other example embodiments, forming the upper chip package may include: preparing an upper printed circuit board including lower pads; forming one or more upper chips, which are electrically connected to the upper printed circuit board and sequentially stacked, on the upper printed circuit board; forming an upper molding resin compound covering the upper printed circuit board having the upper chips; and forming upper bumps to correspond to the lower pads, respectively.

In yet other example embodiments, the lower printed circuit board, the first lower chips, and the lower molding resin compound may constitute a lower chip package.

In still other example embodiments, the method may further include stacking one or more intermediate chip packages between the lower chip package and the upper chip package. Here, the upper chip package and the intermediate chip package may be physically bonded to each other using an intermediate double-sided wiring board and may be electrically connected to each other as well.

In yet other example embodiments, the method may further include forming external connection terminals under the lower printed circuit board. Here, the external connection terminals may be formed in a ball grid array structure or a land grid array structure.

In still other example embodiments, the method may further include forming one or more second lower chips, which are disposed parallel to the first lower chips and sequentially stacked, on the lower printed circuit board before forming the lower molding resin compound.

In yet other example embodiments, the connection bumps may be formed around the lower molding resin compound on the lower printed circuit board.

In still other example embodiments, the connection bumps may be formed at an edge region of a lower surface of the lower printed circuit board. Here, the double-sided wiring board may extend to surround the edge region of the lower surface of the lower printed circuit board having the lower molding resin compound, so that the connection bumps may be electrically connected to the double-sided wiring board having the lower molding resin compound.

In yet another aspect, the present inventive concept is directed to an electronic system including a stack-type semiconductor package. The electronic system includes a processor, an input/output unit performing data communication with the processor, and one or more stack-type semiconductor packages performing data communication with the processor. The stack-type semiconductor package includes a lower printed circuit board having a plurality of interconnections and a plurality of ball lands for connection. One or more first lower chips, which are electrically connected to the plurality of interconnections and sequentially stacked, are disposed on the lower printed circuit board. A double-sided wiring board bonded to the lower molding resin compound and electrically connected to the connection bumps is disposed on the lower molding resin compound. An upper chip package including upper bumps electrically connected to interconnections of the double-sided wiring board and bonded to the double-sided wiring board is disposed on the double-sided wiring board.

In some example embodiments of the present inventive concept, a board, on which the processor and the stack-type semiconductor package are mounted, may be further included.

In yet another aspect, the present inventive concept is directed to a memory module including a stack-type semiconductor package. The memory module includes a board body including a plurality of tabs at one side, and stack-type semiconductor packages mounted on the board body in an array of two columns or more. Here, each of the stack-type semiconductor packages includes a lower printed circuit board having a plurality of interconnections and a plurality of connection bumps. One or more first lower chips, which are electrically connected to the plurality of interconnections and sequentially stacked, are disposed on the lower printed circuit board. A lower molding resin compound is disposed on the lower printed circuit board to cover the first lower chips. A double-sided wiring board bonded to the lower molding resin compound and electrically connected to the connection bumps is disposed on the lower molding resin compound. An upper chip package including upper bumps electrically connected to an interconnection pattern of the double-sided wiring board and bonded to the double-sided wiring board is disposed.

Example embodiments of the present inventive concept have been disclosed herein and, although specific terms are employed, they are used and are to be interpreted in a generic and descriptive sense only and not for purposes of limitation. Accordingly, it will be understood by those of ordinary skill in the art that various changes in form and details may be made from the exemplary embodiments described herein without departing from the spirit and scope of the present inventive concept as set forth in the following claims.

What is claimed is:

1. A stack-type semiconductor package, comprising:
a lower printed circuit board having a plurality of connection bumps disposed on an upper surface of the lower printed circuit board and a plurality of lower interconnections;
at least one first lower chip sequentially stacked on the lower printed circuit board and electrically connected to the plurality of lower interconnections;
a lower molding resin compound disposed on the lower printed circuit board and covering the first lower chips;
a double-sided wiring board bonded to the lower molding resin compound and electrically connected to the connection bumps; and
an upper chip package bonded to the double-sided wiring board and having upper bumps electrically connected to an interconnection pattern of the double-sided wiring board.

2. The semiconductor package of claim 1, wherein the upper chip package comprises:
an upper printed circuit board having lower pads;
one or more upper chips sequentially stacked on an upper surface of the upper printed circuit board and electrically connected to the upper printed circuit board; and
an upper molding resin compound covering the upper printed circuit board having the upper chips, wherein the upper bumps are in contact with the lower pads.

3. The semiconductor package of claim 1, further comprising one or more intermediate chip packages disposed between a lower chip package and the upper chip package,
wherein the lower chip package comprises the lower printed circuit board, the first lower chips, and the lower molding resin compound and wherein the intermediate chip package and the upper chip package are physically bonded and electrically connected to each other through an intermediate double-sided wiring board.

4. The semiconductor package of claim 1, wherein the double-sided wiring board comprises a lower thermosetting resin layer, the interconnection pattern, and an upper thermosetting resin layer, which are sequentially stacked.

5. The semiconductor package of claim 4, wherein the connection bumps are in contact with the interconnection pattern through the lower thermosetting resin layer.

6. The semiconductor package of claim 4, wherein the upper bumps penetrate the upper thermosetting resin layer to contact the interconnection pattern.

7. The semiconductor package of claim 1, further comprising one or more second lower chips sequentially stacked on the lower printed circuit board,
wherein the second lower chips are covered by the lower molding resin compound.

8. The semiconductor package of claim 1, wherein the connection bumps are disposed on the lower printed circuit board outside of the lower molding resin compound.

9. A stack-type semiconductor package, comprising:
a lower printed circuit board having a plurality of connection bumps disposed on a lower surface of the lower printed circuit board and a plurality of lower interconnections;
at least one lower chip sequentially stacked on the lower printed circuit board and electrically connected to the plurality of lower interconnections;
a lower molding compound disposed on the lower printed circuit board and covering the lower chips;
a double-sided wiring board bonded to the lower molding compound, wherein the double-sided wiring board comprises an interconnection pattern disposed between a first insulating layer and a second insulating layer and wherein the connection bumps penetrate the first insulating layer to contact the interconnection pattern; and
an upper chip package bonded to the double-sided wiring board and having upper bumps penetrating the second insulating layer to contact the interconnection pattern of the double-sided wiring board.

10. The semiconductor package of claim 9, wherein the connection bumps are disposed at an edge region of the lower surface of the lower printed circuit board, and wherein the double-sided wiring board extends around the edge region of the lower surface of the lower printed circuit board.

11. The semiconductor package of claim 9, further comprising a plurality of external connection terminals disposed on the lower surface of the lower printed circuit board.

12. The semiconductor package of claim 9, wherein the upper chip package further comprises:
an upper printed circuit board;
at least one upper chip stacked on an upper surface of the upper printed circuit board;
an upper molding resin compound covering the upper chips;
a plurality of upper interconnections; and
a plurality of lower pads,
wherein the upper bumps are electrically connected to the upper chips through the lower pads and the upper interconnections.

13. The semiconductor package of claim 9, wherein each of the first and second insulating layers comprises a thermosetting resin.

14. A stack-type semiconductor package, comprising:
a lower chip package comprising:
a lower printed circuit board having a plurality of connection bumps disposed on an upper surface of the lower printed circuit board and a plurality of lower interconnections;
at least one lower chip disposed on the lower printed circuit board and electrically connected to the plurality of lower interconnections;
a lower molding compound disposed on the lower printed circuit board and covering the lower chips;
a double-sided wiring board bonded to the lower molding compound and including an interconnection pattern electrically connected to the connection bumps; and
an upper chip package comprising:
an upper printed circuit board having a plurality of lower pads disposed on a lower surface of the upper printed circuit board and a plurality of upper interconnections, wherein the lower surface of the upper printed circuit board is bonded to the double-sided wiring board;
at least one upper chip disposed on the upper printed circuit board and electrically connected to the plurality of upper interconnections;
an upper molding compound disposed on the upper printed circuit board and covering the upper chips;
a plurality of upper bumps electrically connected to the interconnection pattern of the double-sided wiring board.

15. The semiconductor package of claim 14, wherein the double-sided wiring board comprises:
a first insulating layer bonded to the lower molding compound;
a second insulating layer bonded to the lower surface of the upper printed circuit board; and
the interconnection pattern disposed between the first and second insulating layers.

16. The semiconductor package of claim 15, wherein:
the connection bumps penetrate the first insulating layer to contact the interconnection pattern; and
the upper bumps penetrate the second insulating layer to contact the interconnection pattern.

17. The semiconductor package of claim 15, wherein:
the first insulating layer comprises a plurality of lower via holes; and
the second insulating layer comprises a plurality of upper via holes.

18. The semiconductor package of claim 17, wherein
the connection bumps penetrate the lower via holes to contact the interconnection pattern; and
the upper bumps penetrate the upper via holes to contact the interconnection pattern.

19. The semiconductor package of claim 14, wherein the connection bumps are disposed on connection bump pads electrically connected to the lower interconnections.

20. The semiconductor package of claim 14, wherein the lower chip package further comprises a plurality of external connection terminals disposed on a lower surface of the lower printed circuit board.
